(19) United States
(12) Patent Application Publication
(10) Pub. No.: US 2009/0026533 A1
(43) Pub. Date: Jan. 29, 2009

(54) Trench MOSFET with multiple P-bodies for ruggedness and on-resistance improvements

(75) Inventor: Fwu-Iuan Hshieh, Saratoga, CA (US)

Correspondence Address: Bo-In Lin, 13445 Mandoli Drive, Los Altos Hills, CA, 94022, US

(73) Assignee: Force-MOS Technology Corporation

(21) Appl. No.: 11/880,939

(22) Filed: Jul. 24, 2007

(51) Int. Cl. H01L 29/78; H01L 21/336

(52) U.S. Cl. 257/330; 438/270; 257/E29.262; 257/E21.41

(57) ABSTRACT

A vertical semiconductor power device includes a plurality of semiconductor power cells having a drain disposed at a bottom of a semiconductor substrate. Each of the cells includes a gate surrounded by a body region encompassing a source region. The body region further includes multiple body-dopant implanted regions having a non-Gaussian distribution dopant profile for reducing a width of a transition region transitioning between the multiple body-dopant implanted regions and an epitaxial region underneath having a different conductivity type from the multiple body-dopant implanted regions.

### BACKGROUND OF THE INVENTION

1. Field of the Invention

This invention relates generally to the cell structure, device configuration and fabrication process of power semiconductor devices. More particularly, this invention relates to a novel and improved device configuration and processes to manufacture trench MOSFET device with multiple P-bodies for ruggedness and on-resistance improvements.

2. Description of the Related Art

Conventional configurations of the trench semiconductor power devices in providing front metal as source metal contact and gate pad are confronted with the technical difficulties that the conventional power devices have a higher on-resistance for DC/DC applications that requires deep trenches in order to prevent a hoot through phenomenon.

Referring to FIG. 1A doe a circuit diagram for applying the semiconductor power device such as the MOSFET Q1 and Q2 for a DC/DC application. As the first MOSFET Q1 is turned on, the voltage at the node A is Vm and the gate of the second MOSFET Q2 is self-biased to Vm{Qgd/(Qgd+Qgs)}. In the meantime, if the voltage on the gate 2 of the MOSFET Q2 is greater or equal to the threshold voltage Vg2>Vth, then MOSFET Q2 is self-turned on without any bias. A shoot-through problem occurs as both MOSFET Q1 and Q2 are turned on at the same time. The shoot through phenomenon can inadvertently destroy the entire circuit and cause major device malfunctions. In order to prevent the occurrence of a shoot-through, it is required to provide the MOSFET Q1 and Q2 such that (Qgd/Qgs)<1 to reduce the self-biased voltage.

Referring to FIG. 1B for a side cross sectional view of a conventional trench MOSFET device manufactured typically with a single P-body ion implantation process. FIG. 1C is a diagram for illustrating the variations of the dopant ion concentrations along a vertical line A-B-C-D that cut through different regions in the MOSFET device as shown in FIG. 1B. FIG. 1B shows the P-body has a body depth of Xpj. Furthermore, FIG. 1B illustrates that the electric charges Qgd stored in the gate-drain capacitor Cgd is a function of the interfacial area between the trench gate and the N-epitaxial region and the electric charges Qgs stored in the gate-source capacitor Cgs is a function of the depth of the trench gate. In order to prevent a shoot through problem, it is necessary to make (Qgd/Qgs)<1 and that generally is achievable by making a deep trench, i.e., a trench depth greater than 1.0 μm, to increase Qgs.

Referring to FIG. 1C for the doping profile for a conventional trench MOSFET device that has a single P-body formed by applying a low or medium energy ion implantation and higher temperature or a longer drive-in process to form the P-body. As show in the doping profile along the vertical line A-B-C-D, the P-body drive in process either with a high temperature or a longer drive-in time, cause the P-body ion to drive into the N-epitaxial region near the trench bottom. A wider N-transition region is formed that causes the drain-to-source resistance Rds to increase. FIG. 1D is a doping profile diagram to show the ion diffusion profiles at different temperature and different drive-in time. According to the Gaussiian doping profile version the diffusion time or temperature functional relationship as shown in FIG. 1D, the N-transition region as that shown in FIG. 1C is increased due to a-longer drive-in time or a higher diffusion temperature resulting from the slop reduction of the P-body dopant profile according to FIG. 1D.

As more semiconductor power devices are now employed in the DC/DC applications, there is an urgent demand to provide semiconductor power devices that-has deep trench to prevent the shoot through problems without sacrificing the device performance arising from higher Rds as described above. Therefore, a need at the moment exists in the art of designing and manufacturing semiconductor power devices to provide new and improved device configuration to resolve such limitations.

### SUMMARY OF THE PRESENT INVENTION

It is therefore an aspect of the present invention to provide new and improved semiconductor power device configuration and manufacture processes for providing semiconductor power devices with double or triple implanted body regions. These double or triple implanted body regions are then diffused at lower temperature and shorter drive-in time to prevent extensive body dopant ions to diffuse into the epitaxial layer below the body regions. The N-transition region at the interface between the bottom of the body regions and the top of the epitaxial layer has a significant reduced width. The on resistance caused by the reduced dopant concentration at the transition region is therefore significantly reduced because the transition region has much narrower width across the depth below the double or triple implanted body regions.

Another aspect of this invention is the improvement of the device ruggedness. The ruggedness of the device is improved because the body region has substantially a higher and more uniform body dopant distribution over a significant portion over the depth of the body regions. The base of the parasitic N+PN bipolar transistor formed between the source-body-epitaxial layers has a reduced current gain with higher body dopant concentration.

Briefly, in a preferred embodiment, the present invention discloses a vertical semiconductor power device. The vertical semiconductor power device includes a plurality of semiconductor power cells having a drain disposed at a bottom of a semiconductor substrate. Each of the cells includes a gate surrounded by a body region encompassing a source region. The body region further includes multiple body-dopant implanted regions having a non-Gaussian distribution dopant profile for reducing a width of a transition region transitioning between the multiple body-dopant implanted regions and an epitaxial region underneath having a different conductivity type from the multiple body-dopant implanted regions. In an exemplary embodiment, the gate further includes a polysilicon filling a trench opened in the semiconductor substrate. In another exemplary embodiment, the gate further includes a polysilicon disposed on a top surface of the semiconductor substrate over a region surrounded by the multiple body-dopant implanted regions. In another exemplary embodiment, the multiple body-dopant implanted regions further includes a deep body region implanted with body dopant ions having an implant energy of approximately 200 Kev to 600 Kev and a shallow body region implanted with body dopant ions having an implant energy approximately 10 KeV to 200 KeV. In another exemplary embodiment, the multiple body-dopant implanted regions further includes a deep body region implanted with body dopant-ions having an implant energy of approximately 300 Kev to 600 Kev, a medium body region implanted with body dopant ions having an implant energy approximately 100 KeV to 300 KeV and a shallow body region implanted with body dopant ions having an implant energy approximately 10 KeV to 100 KeV. In another exemplary embodiment, the vertical semiconductor power device further comprising a N-channel MOSFET device and the multiple body-dopant implanted regions comprising multiple P-body implanted regions. In another exemplary embodiment, the vertical semiconductor power device further comprising a P-channel MOSFET device and the multiple body-dopant implanted regions comprising multiple N-body implanted regions. In another exemplary embodiment, the vertical semiconductor power device further comprising a trench MOSFET device and the multiple body-dopant implanted regions surrounding a trench gate of the MOSFET device. In another exemplary embodiment, the semiconductor power device further includes a source/body contact trench opened through an insulation layer covering the trench MOSFET device extending into the semiconductor substrate for contacting the source regions and the multiple body implanted regions wherein the contact trench filled with a barrier metal and a tungsten plug electrically connecting to source metal disposed on top of the insulation layer. In another exemplary embodiment, the semiconductor power device further include a gate contact trench opened through an insulation layer covering the trench MOSFET device extending into the trench gate and filled with a barrier metal and a tungsten plug and electrically connecting to a gate pad disposed on top of the insulation layer. In another exemplary embodiment, the vertical semiconductor power device further comprising a trenched MOSFET device wherein the trench is deeper than one micrometer (1.0 μm) and the trenched MOSFET device having an electrical characteristic of (Qgd/Qgs)<1 where Qgd representing electric charges stored in a gate-drain capacitor and Qgs representing electric charges stored in a gate-source capacitor and the MOSFET device having a ON-resistance in a range of 1 mohm˜5 ohm.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

FIG. 1A is a circuit diagram for showing a DC/DC converter implemented with semiconductor power device such as MOSFET Q1 and Q2 that require deep trench MOSFET devices for preventing a shoot through problem.

FIG. 1B is a side cross sectional view and of a conventional MOSFET device that has a single body region manufactured with single body implantation.

FIG. 1C is a diagram for illustrating the dopant profile of a MOSFET with a single-implantation body region where the on-resistance is increased due to a wide transition region between the interface region of the body and epitaxial layer in a semiconductor substrate.

FIG. 1D shows the Gaussian doping profile versus diffusion time and temperature wherein a N-transition region has an increased width with increased diffusion time or diffusion temperature due to a slope reduction of the P-body dopant profile along the depth of the body region and the epitaxial region.

FIG. 2A is a side cross sectional view of an improved MOSFET device of this invention with dual-implanted body region.

FIG. 2B is a dopant profile diagram for showing the concentration variation of the dopant concentration of the double-implanted body regions of this invention.

FIG. 2C is a dopant profile diagram for comparing the variations of the dopant concentrations of the dual-implanted body region of this invention with the single body region according to a conventional manufacturing method.

FIG. 3 is another dopant profile diagram for illustrating the variation of the dopant concentration when a triple body implantation process is applied to form triple-implanted body region.

FIGS. 4A to 4E are a serial of side cross sectional views for showing the processing steps for fabricating a MOSFET device as shown in FIGS. 2A and 3 of this invention.

### DETAILED DESCRIPTION OF THE PREFERRED EMBODIMENT

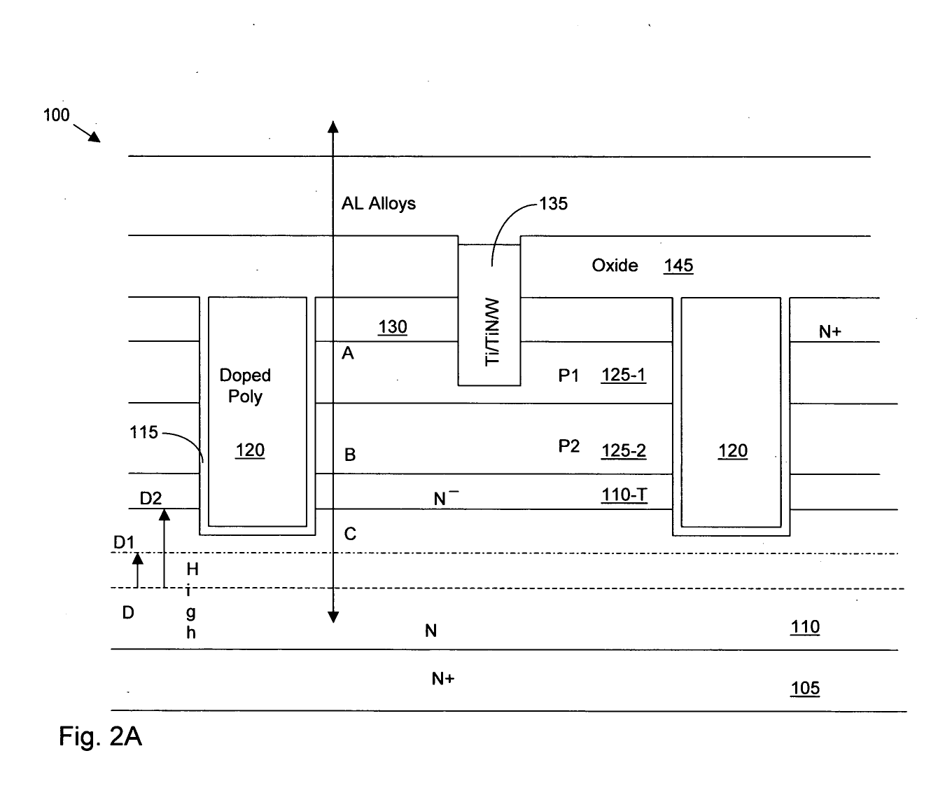

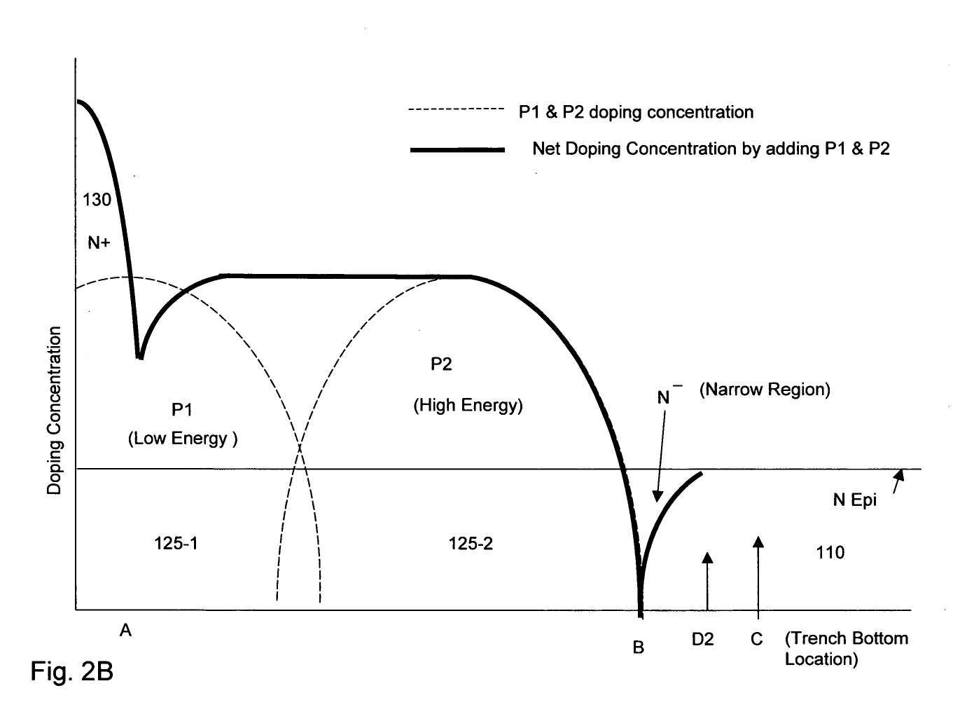

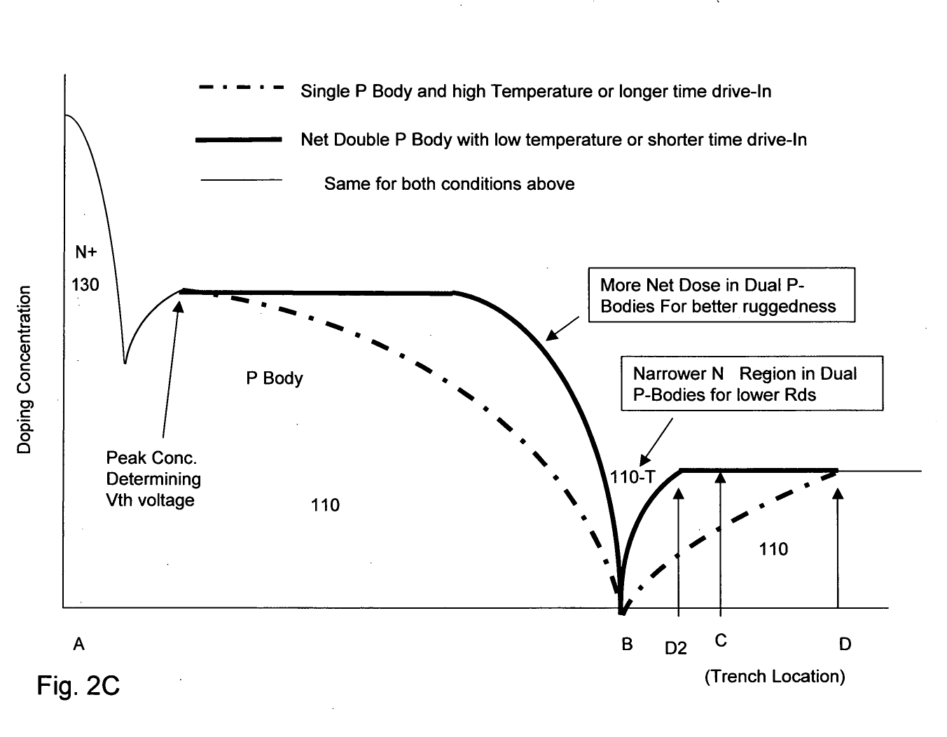

Referring to FIG. 2A for a side cross-sectional view of a trench MOSFET 100 manufactured by applying a dual P-body ion implantation process of this invention to reduce the on resistance Rds. The detail processing steps in applying the dual P-body ion implantation process are further discussed below. The trenched MOSFET 100 is supported on a substrate 105 formed with an epitaxial layer 110. The MOSFET device 100 includes trenched gates 120 disposed in a trench with a gate insulation layer 115 formed over the walls of the trench. A body region 125 that is doped with a dopant of second conductivity type, e.g., P-type dopant, extends between the trenched gates 120. The P-body regions 125 encompass the source regions 130 doped with the dopant of first conductivity, e.g., N+ dopant. The source regions 130 are formed near the top surface of the epitaxial layer surrounding the trenched gates 120. In order to improve the source/body contact, a P+ dopant region (not shown) is formed at the bottom of the source/body contact trenches 135 opened through an overlying insulation layer 145 and filled with tungsten surrounded by a Ti/TiN barrier layer. An aluminum alloy layer 150 to function as a source metal and gate metal (not shown) is formed and patterned to contact the source/body contact plugs 135 and the gate contact plugs (not shown) to the gate 120.

For the purpose of improving the on resistance for the trench MOSFET with a deep trench for DC/DC applications, the body regions 125 are formed as a first dopant body regions 125-1 (P1) a and a second body dopant region 125-2 (P-2). As a drive-in process is performed in forming the dual P-body regions 125-1 and 125-2, a transition epitaxial region 110-T having a N− dopant concentration is formed immediately below the second P-body region 125-2. The advantage of this invention is the shrinking of the N-transition region 110-T when compared to the conventional process. As will be explained below the N-transition region may extend to a depth of D2 or D1 when conventional single P-body dopant implantation process is performed. Since the N-transition region 125-T is much narrower than the conventional device, the on-resistance Rds is significantly reduced.

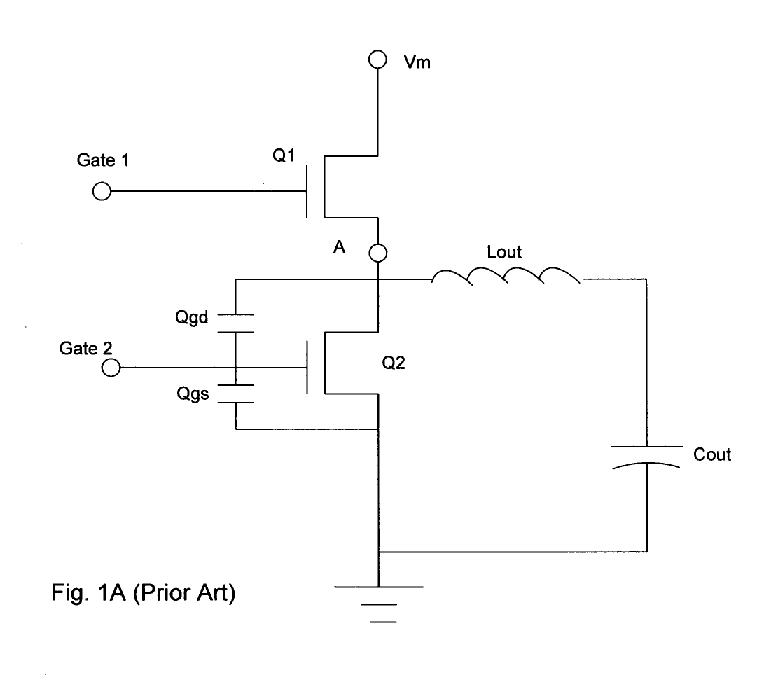

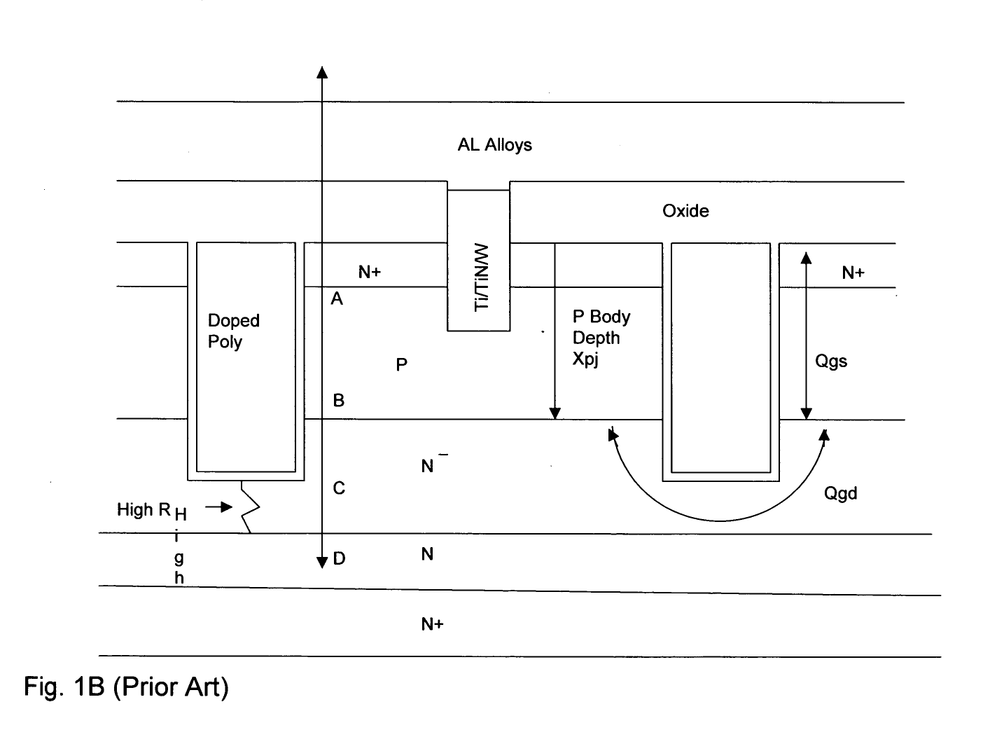

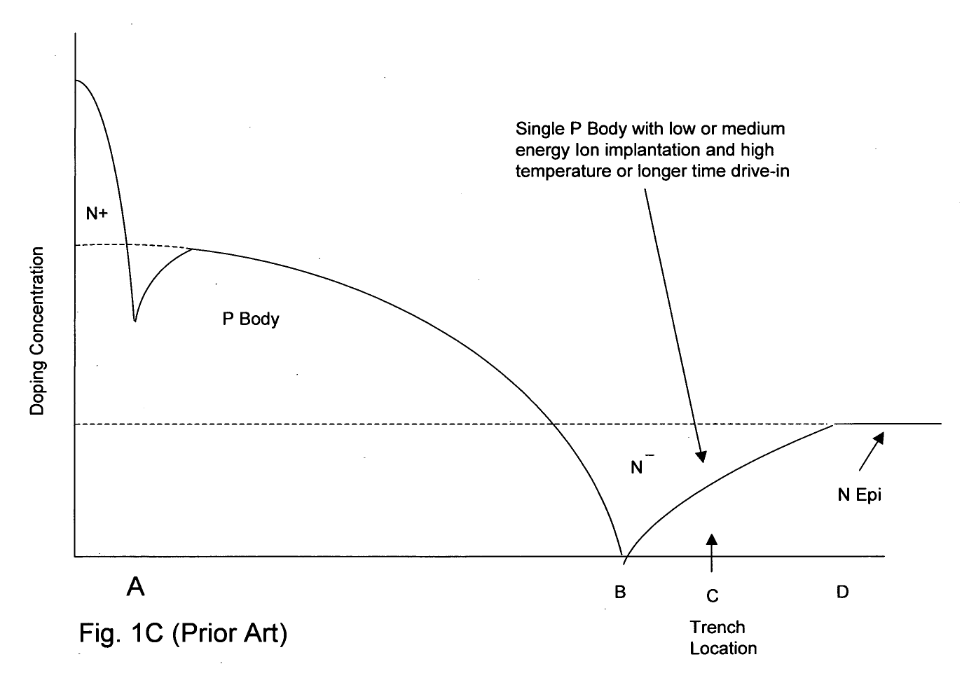

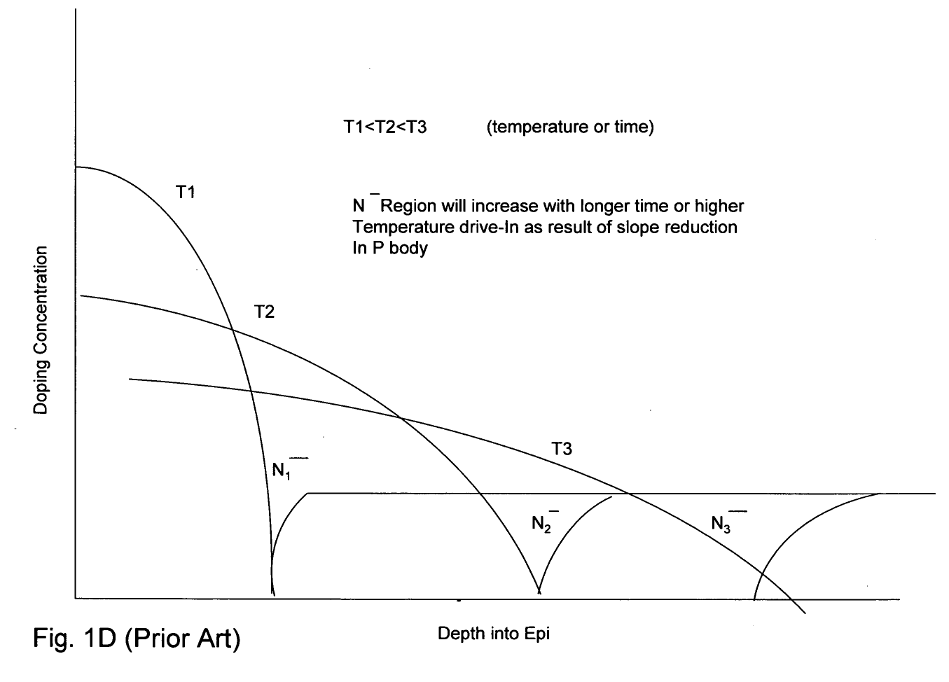

Referring to FIG. 2B for a dopant profile along the vertical line A-B-C-D extending from the source region 130 through the dual body regions 125-1 and 125-2, then through the N-transition region 110-T and further below to reach the epitaxial layer 110. The dopant profile includes a high energy second body implant region 125-2 with a dopant profile shown as P2 overlapping with a low energy body dopant implant region 125-1 with a dopant profile shown as P1. The body regions 125-1 and 125-2 are driven in by using a low temperature and short drive-in time such that the body ions of the lower second body region 125-2 do not diffuse extensively into the N-type epitaxial layer 110. Therefore, the N-transition region 110-T is much narrower when compared to the transition region shown in FIG. 1B. Referring to FIG. 2C for a more specific comparison for the dopant profiles achieved by applying a method of this invention versus the conventional method. The solid line shows the dopant profile when a double high/low energy body implants are applied and the dotted line shows the dopant profile when a single body implant is applied according to the conventional method of manufacture. The comparisons clearly illustrate that the body-dopant distribution of a device when manufactured by the method of this invention has a sharper decrease immediately near the bottom of the body region. Furthermore, because the double body implant operations of this invention that applies a body drive-in process using a temperature and short drive-in time, there are only limited amount of body dopant ions diffused into the epitaxial layer 110 during the body dopant drive-in process. For this reason, unlike the conventional device where the dopant profile is shown by the dotted line, the body dopant concentration decrease significantly at a shorter distance below the bottom of the high-energy implanted body region 125-2. For this reason, the width of the N-transition region 110-T is much narrower when compared with the single body region device. The higher net body dopant concentration in the body region further increases the ruggedness of the device. This is because the body region now has substantially a higher and more uniform body dopant distribution over a significant portion over the depth of the body regions. The body region is functioning as a base of the parasitic N+PN bipolar transistor formed between the source-body-epitaxial layers. The higher dopant concentration has an effect to reduce a current gain of the N+PN transistor thus increasing the ruggedness of the MOSFET device.

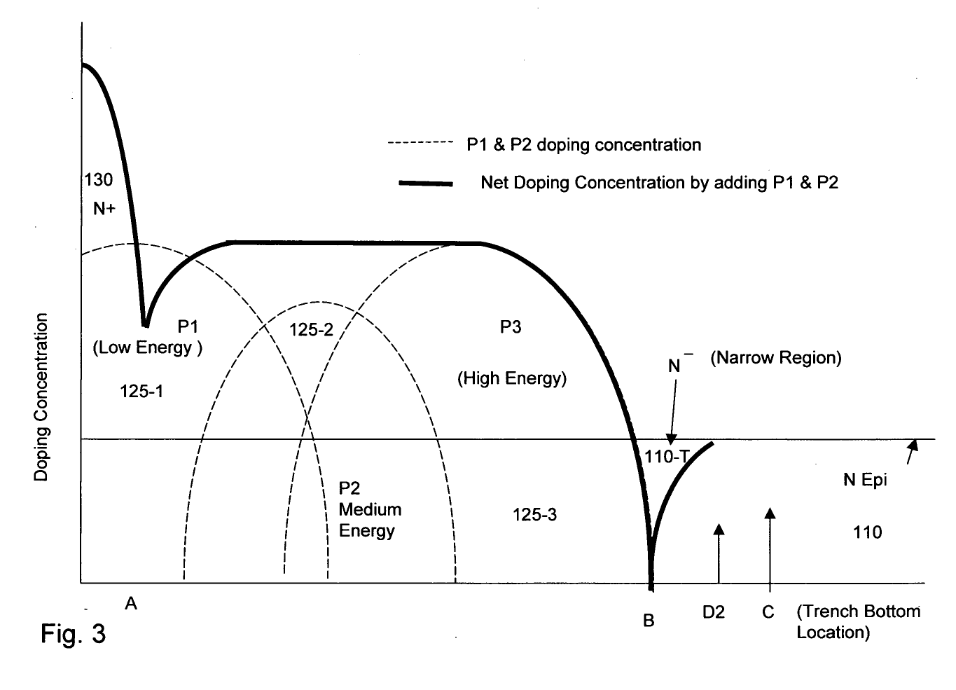

FIG. 3 is a diagram for showing the dopant profile for an alternate embodiment of a trench MOSFET with deep trench and having a triple implanted body regions 125-1, 125-2 and 125-3. The deepest body dopant region 125-3 is implanted with a high energy. The middle body dopant region 125-2 is implanted with a medium energy and the shallow body dopant region 125-1 is implanted with a low energy. The trip implanted body regions 125-1 to 125-3 are driven in with low temperature and short drive-in time such that the N-transition region 110-T is narrower to further reduce the on resistance and the ruggedness is improved with body dopant distribution more uniform along the depth of the body regions 125-1 to 125-3. Compared to the double-implanted body regions, the MOSFET with triple-implanted body region has a further advantage that less N⁻ region and shorter temperature cycle are achieved.

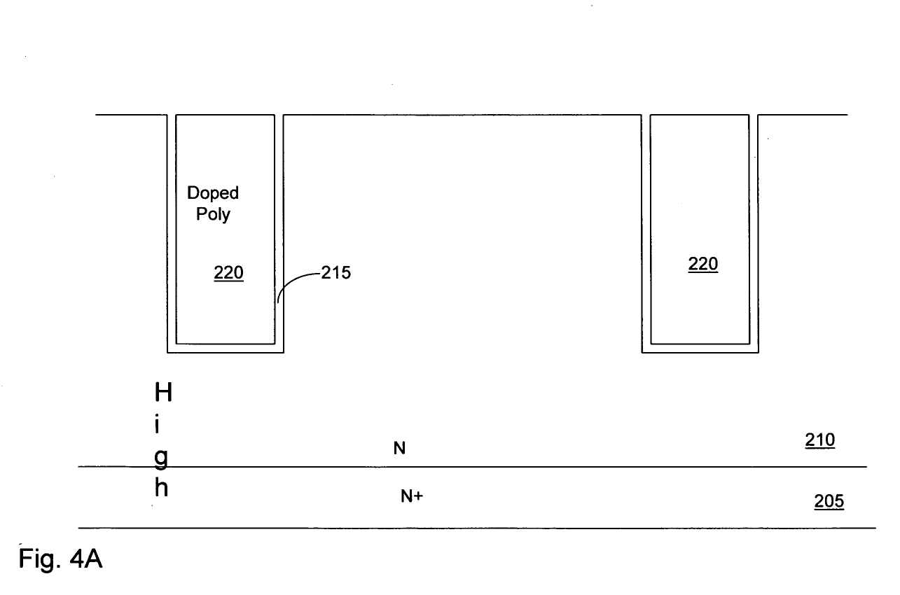

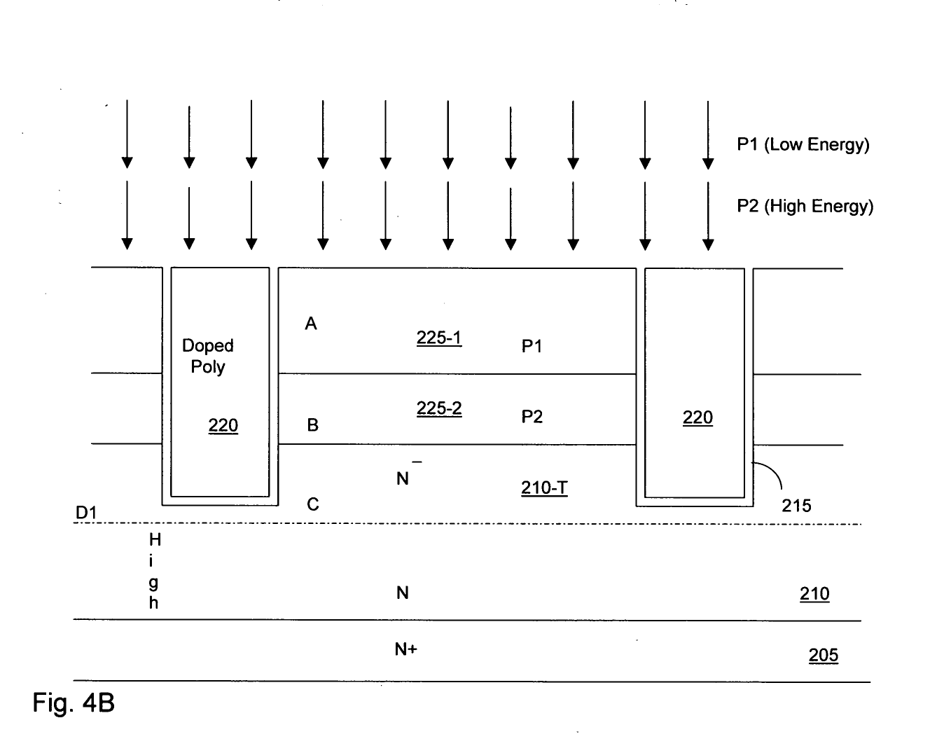

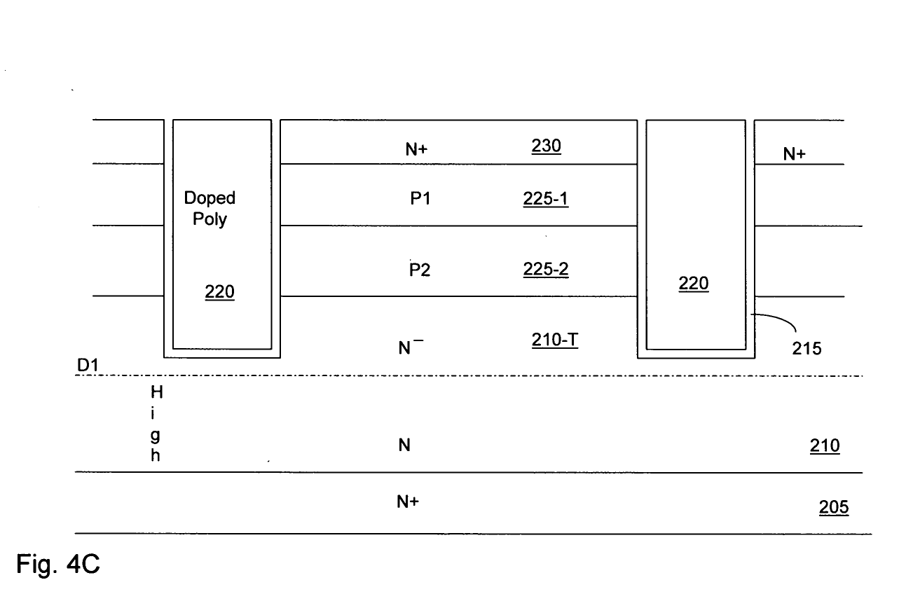

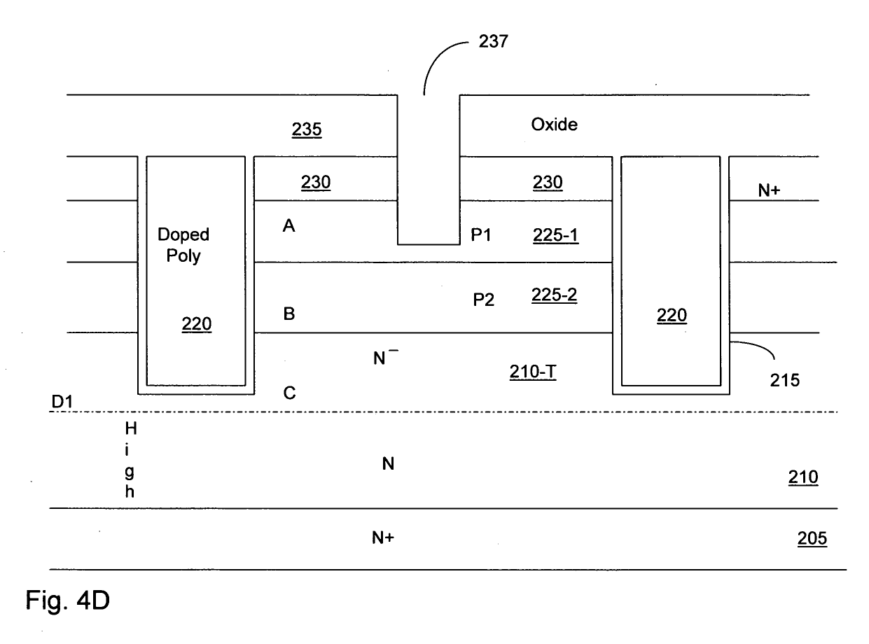

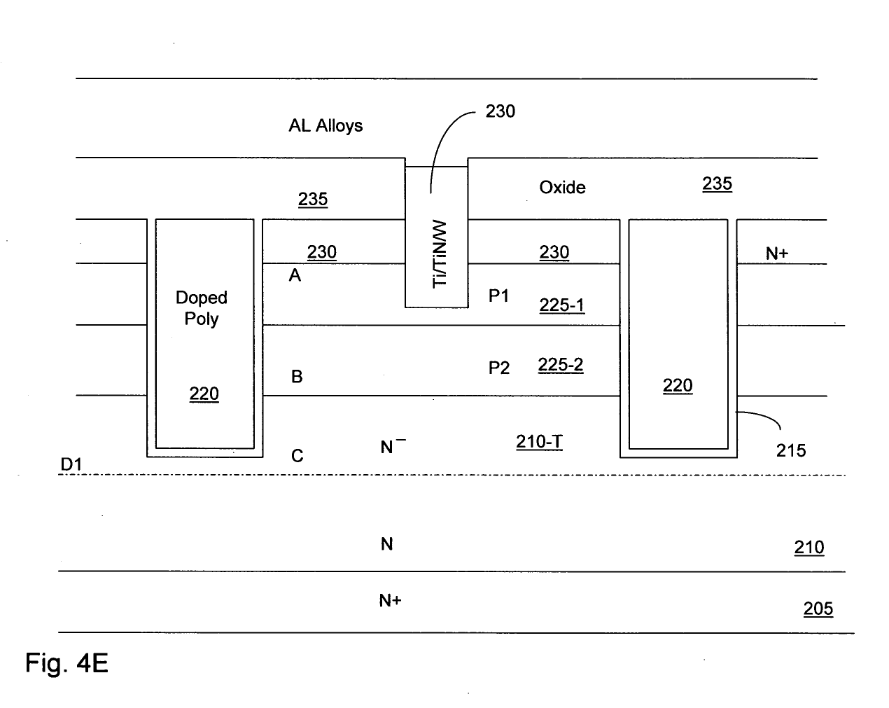

FIGS. 4A to 44E are a series of side cross sectional views for illustrating the processing steps to manufacture the MOSFET device as that shown in FIG. 2A. In FIG. 4A, a trench mask (not shown) is applied to open a plurality of trenches in an epitaxial layer 210 supported on a substrate 205 by employing a dry silicon etch process. An oxidation process is then performed to form an oxide layer covering the trench walls. The trench is oxidized with a sacrificial oxide to remove the plasma damaged silicon layer during the process of opening the trench. Then an oxide layer 215 is grown. Then the manufacturing processes continue with a step of depositing a polysilicon layer 220 to fill the trench and covering the top surface and then doped with an N+ dopant. The polysilicon layer 220 filling the trenches are either etched back or removed by applying a chemical mechanical planarization process (CMP) to remove the polysilicon above the top surface.

In FIG. 4B, the manufacturing processes proceed by applying a body mask (not shown) for performing dual P-body implantations first with a high energy body dopant implant into the deeper region 225-2 followed by a low energy body dopant implant to form the shallower body region 225-1. Then, a slightly elevated temperature is applied to diffuse the P-body 225-1 and 225-2 into the epitaxial layer 210 with a narrow N-transition region 210-T immediately below the deeper body region 225-2. Then in FIG. 4C, the body mask is removed followed by applying a source mask (not shown) for implanting a N+ source dopant to form the source regions 230 followed by applying an elevated temperature to diffuse the source regions 230 further into the body region 225. In FIG. 4D, an oxide deposition is then carried out to form a thick oxide layer 235 covering over the top surface of the device. Then, a dry contact oxide etch is carried out with a contact etch mask (not show) to open trenches 237 through the oxide layer 235 into the body regions 225 between the trenched gates 220. Then a boron ion implantation is carried out to form P+ region (not shown) below the trenches 237 as doped metal contact regions. In FIG. 4E, a Ti/TiN/W is deposited into the metal contact trenches 230 wherein the metal contact plugs include tungsten plugs surrounded with Ti/TiN barrier layer. Then an etch back process of tungsten and also of Ti/TiN are carried out followed by the Ti/aluminum alloys deposition and patterning processes to form the source metal and the gate pad following the standard manufacturing processes not specifically shown.

Alternatively, instead of the dual body dopant implantation process as shown in FIG. 4B, a triple body dopant implantation may be carried out with a high energy, a medium energy and a low energy body dopant implantation to form triple-implanted body regions with a dopant profile as that shown in FIG. 3.

According to above descriptions, this invention further discloses a method for manufacturing a vertical semiconductor power device that includes a plurality of semiconductor power cells with a drain disposed at a bottom of a semiconductor substrate with each of the cells includes a gate surrounded by a body region encompassing a source region. The method further includes a step of performing multiple body-dopant implantations to form multiple body-dopant implanted regions having a non-Gaussian distribution dopant profile for reducing a width of a transition region transitioning between the multiple body-dopant implanted regions and an epitaxial region underneath having a different conductivity type from the multiple body-dopant implanted regions. In an exemplary embodiment, the step of performing multiple body-dopant implantations further includes a step of implanting a deep body region with body dopant ions having an implant energy of approximately 200 Kev to 600 Kev and implanting a shallow body region with body dopant ions having an implant energy approximately 10 KeV to 200 KeV. In another exemplary embodiment, the step of performing multiple body-dopant implantations further includes a step of implanting a deep body region with body dopant ions having an implant energy of approximately 300 Kev to 600 Kev, implanting a medium body region with body dopant ions having an implant energy of 100 KeV to 300 KeV, and implanting a shallow body region with body dopant ions having an implant energy approximately 10 KeV to 100 KeV. In another exemplary embodiment, the method further includes a step of forming the vertical semiconductor power device as a trenched MOSFET device with a trench deeper than one micrometer (1.0 μm). And, the method further includes another step of forming the MOSFET device with an electrical characteristic of (Qgd/Qgs)<1 where Qgd representing electric charges stored in a gate-drain capacitor and Qgs representing electric charges stored in a gate-source capacitor and forming the MOSFET device having a ON-resistance in a range of 1 mohm˜5 ohm.

According to above descriptions, this invention further discloses an electronic device includes a vertical semiconductor power device that further includes a plurality of semiconductor power cells with a drain disposed at a bottom of a semiconductor substrate and each of the cells includes a gate surrounded by a body region encompassing a source region. The body region further includes multiple body-dopant implanted regions having a non-Gaussian distribution dopant profile for reducing a width of a transition region transitioning between the multiple body-dopant implanted regions and an epitaxial region underneath having a different conductivity type from the multiple body-dopant implanted regions. In an exemplary embodiment, the electronic device includes a DC-DC converter. In another exemplary embodiment, the multiple body-dopant implanted regions further includes a deep body region implanted with body dopant ions having an implant energy of approximately 200 Kev to 600 Kev and a shallow body region implanted with body dopant ions having an implant energy approximately 10 KeV to 200 KeV. In another exemplary embodiment, the multiple body-dopant implanted regions further includes a deep body region implanted with body dopant ions having an implant-energy 0f approximately 300 Kev to 600 Kev, a medium body region implanted with body dopant ions having an implant energy approximately 100 KeV to 300 KeV (OK), and a shallow body region implanted with body dopant ions having an implant energy approximately 10 KeV to 100 KeV. In another exemplary embodiment, the vertical semiconductor power device further includes a trenched MOSFET device wherein the trench is deeper than one micrometer (1.0 μm) and the trenched MOSFET device having an electrical characteristic of (Qgd/Qgs)<1 where Qgd representing electric charges stored in a gate-drain capacitor and Qgs representing electric charges stored in a gate-source capacitor and the MOSFET device having a ON-resistance in a range of 1 mohm˜5 ohm.

Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

I claim:

1. A vertical semiconductor power device comprising a plurality of semiconductor power cells having a drain disposed at a bottom of a semiconductor substrate with each of said cells comprising a gate surrounded by a body region encompassing a source region wherein:
said body region further comprising multiple body-dopant implanted regions having a non-Gaussian distribution dopant profile for reducing a width of a transition region transitioning between said multiple body-dopant implanted regions and an epitaxial region underneath having a different conductivity type from said multiple body-dopant implanted regions.

2. The vertical semiconductor power device of claim 1 wherein:
said gate further comprising a polysilicon filling a trench opened in said semiconductor substrate.

3. The vertical semiconductor power device of claim 1 wherein:
said gate further comprising a polysilicon disposed on a top surface of said semiconductor substrate over a region surrounded by said multiple body-dopant implanted regions.

4. The vertical semiconductor power device of claim 1 wherein:
said multiple body-dopant implanted regions further comprising a deep body region implanted with body dopant ions having an implant energy of approximately 200 Kev to 600 Kev and a shallow body region implanted with body dopant ions having an implant energy approximately 10 KeV to 200 KeV.

5. The vertical semiconductor power device of claim 1 wherein:
said multiple body-dopant implanted regions further comprising a deep body region implanted with body dopant ions having an implant energy of approximately 300 Kev to 600 Kev, a medium body region implanted with body dopant ions having an implant energy approximately 100 KeV to 300 KeV and a shallow body region implanted with body dopant ions having an implant energy approximately 10 KeV to 100 KeV.

6. The vertical semiconductor power device of claim 1 wherein:
said vertical semiconductor power device further comprising a N-channel MOSFET device and said multiple body-dopant implanted regions comprising multiple P-body implanted regions.

7. The vertical semiconductor power device of claim 1 wherein:
said vertical semiconductor power device further comprising a P-channel MOSFET device and said multiple body-dopant implanted regions comprising multiple N-body implanted regions.

8. The vertical semiconductor power device of claim 1 wherein:
said vertical semiconductor power device further comprising a trench MOSFET device and said multiple body-dopant implanted regions surrounding a trench gate of said MOSFET device.

9. The vertical semiconductor power device of claim 8 further comprising:
a source/body contact trench opened through an insulation layer covering said trench MOSFET device extending into said epitaxial layer on semiconductor substrate for contacting said source regions and said multiple body implanted regions wherein said contact trench filled with a barrier metal and a tungsten plug electrically connecting to source metal composed of Ti and aluminum alloys disposed on top of said insulation layer.

10. The vertical semiconductor power device of claim 8 further comprising:
a gate contact trench opened through an insulation layer covering said trench MOSFET device extending into said trench gate and filled with a barrier metal and a tungsten plug and electrically connecting to a gate pad disposed on top of said insulation layer.

11. The vertical semiconductor power device of claim 1 wherein:
said vertical semiconductor power device further comprising a trenched MOSFET device wherein said trench is deeper than one micrometer (1.0 μm) and said trenched MOSFET device having an electrical characteristic of (Qgd/Qgs)<1 where Qgd representing electric charges stored in a gate-drain capacitor and Qgs representing electric charges stored in a gate-source capacitor and said MOSFET device having a ON-resistance in a range of 1 mohm ˜5 ohm.

12. A method for manufacturing a vertical semiconductor power device comprising a plurality of semiconductor power cells having a drain disposed at a bottom of a semiconductor substrate with each of said cells comprising a gate surrounded by a body region encompassing a source region comprising:
performing multiple body-dopant implantations to form multiple body-dopant implanted regions having a non-Gaussian distribution dopant profile for reducing a width of a transition region transitioning between said multiple body-dopant implanted regions and an epitaxial region underneath having a different conductivity type from said multiple body-dopant implanted regions.

13. The method of claim 12 wherein:
said step of performing multiple body-dopant implantations further comprising a step of implanting a deep body region with body dopant ions having an implant energy of approximately 200 Kev to 600 Kev and implanting a shallow body region with body dopant ions having an implant energy approximately 10 KeV to 200 KeV.

14. The method of claim 12 wherein:
said step of performing multiple body-dopant implantations further comprising a step of implanting a deep body region with body dopant ions having an implant energy of approximately 300 Kev to 600 Kev, implanting a medium body region with body dopant ions having an implant energy of 100 KeV to 300 KeV, and implanting a shallow body region with body dopant ions having an implant energy approximately 10 KeV to 100 KeV.

15. The method of claim 12 further comprising:
forming said vertical semiconductor power device as a trenched MOSFET device with a trench deeper than one micrometer (1.0 μm); and
forming said MOSFET device with an electrical characteristic of (Qgd/Qgs)<1 where Qgd representing electric charges stored in a gate-drain capacitor and Qgs representing electric charges stored in a gate-source capacitor and forming said MOSFET device having a ON-resistance in a range of 1 mohm˜5 ohm.

16. An electronic device comprising a vertical semiconductor power device that further includes a plurality of semiconductor power cells having a drain disposed at a bottom of a semiconductor substrate with each of said cells comprising a gate surrounded by a body region encompassing a source region wherein:
said body region further comprising multiple body-dopant implanted regions having a non-Gaussian distribution dopant profile for reducing a width of a transition region transitioning between said multiple body-dopant implanted regions and an epitaxial region underneath having a different conductivity type from said multiple body-dopant implanted regions.

17. The electronic device of claim 16 wherein:
said electronic device further comprising a DC-DC converter.

18. The electronic device of claim 16 wherein:
said multiple body-dopant implanted regions further comprising a deep body region implanted with body dopant ions having an implant energy of approximately 200 Kev to 600 Kev and a shallow body region implanted with body dopant ions having an implant energy approximately 10 KeV to 200 KeV.

19. The electronic device of claim 16 wherein:
said multiple body-dopant implanted regions further comprising a deep body region implanted with body dopant ions having an implant energy of approximately 300 Kev to 600 Kev, a medium body region implanted with body dopant ions having an implant energy approximately 100 KeV to 300 KeV and a shallow body region implanted with body dopant ions having an implant energy approximately 10 KeV to 100 KeV.

20. The electronic device of claim 16 wherein:
said vertical semiconductor power device further comprising a trenched MOSFET device wherein said trench is deeper than one micrometer (1.0 μm) and said trenched MOSFET device having an electrical characteristic of (Qgd/Qgs)<1 where Qgd representing electric charges stored in a gate-drain capacitor and Qgs representing electric charges stored in a gate-source capacitor and said MOSFET device having a ON-resistance in a range of 1 mohm˜5 ohm.
